(19) United States
(12) Patent Application Publication
(10) Pub. No.: US 2025/0075796 A1
(43) Pub. Date: Mar. 6, 2025

(54) CONNECTOR WITH PRESSURIZED SEALING CHAMBER FOR PROCESS TUBE OF A PROCESS FURNACE

(71) Applicant: LUXEMBOURG INSTITUTE OF SCIENCE AND TECHNOLOGY (LIST), Esch-sur-Alzette (LU)

(72) Inventors: Didier ARL, Esch-sur-Alzette (LU); Olivier BLANCHARD, Les Ulis (FR); François NEUILLY, Esch-sur-Alzette (LU); Pierre-Emmanuel PONCET, Les Ulis (FR); Mathieu GERARD, Esch-sur-Alzette (LU)

(21) Appl. No.: 18/725,952

(22) PCT Filed: Dec. 29, 2022
(86) PCT No.: PCT/EP2022/087984

§ 371 Date: Jul. 1, 2024

(30) Foreign Application Priority Data
Dec. 31, 2021 (FR) 2114719
Dec. 31, 2021 (LU) 501139

(51) Int. Cl. F16J 15/46; C23C 16/44; F16L 17/02

(52) U.S. Cl. CPC F16J 15/46; C23C 16/4409; F16L 17/02

(57) ABSTRACT

A connector for a process tube, comprising an annular body; an engagement bore formed in the annular body, for receiving an end of the process tube; a sealing groove formed in the engagement bore, for receiving at least two annular gaskets for contacting the end of the process tube; wherein the annular body comprises a sealing port fluidly connected with the sealing groove so as to allow applying a gas pressure in the sealing groove between the at least two annular gaskets.

### CROSS-REFERENCE TO RELATED APPLICATIONS

The present invention is the US national stage under 35 U.S.C. § 371 of International Application No. PCT/EP2022/087984 filed on Dec. 29, 2022, which claims the priority of application LU501139 filed on Dec. 31, 2021, and FR2114719 filed Dec. 31, 2021 the contents of which (text, drawings and claims) are incorporated here by reference in their entirety.

### FIELD

The invention is directed to the field of gas processing in a process tube, e.g., in the presence of heat and/or vacuum. More specifically the invention is directed to connecting a process tube of a gas process tube machine, e.g., a furnace, to a process gas supply.

### BACKGROUND

A laboratory process tube furnace generally comprises a frame equipped with electrical resistors and temperature control equipment, and an insulated cover hinged to an upper portion of the frame. The cover and frame form a transversal passage for receiving a process tube. The latter is usually made of a high-temperature resistant material such as alumina. The process tube forms an inner passage intended to receive a substrate and process gas so as to carry out heat processes. A connector or sealing flange is mounted at each end of the process tube so as to sealingly isolate its inner passage from the ambient and inject one or more process gas thereinto. Due to the very-high temperatures of the above process, e.g., more than 1000° C., the material of the process tube is a refractory material like ceramic alumina, where the process tube is manufactured by powder technology. Due to that manufacturing process, the outer surface of the process tube can show large geometric tolerance as well as large surface condition tolerances. This means that the connector or sealing flanges mounted that the process tube ends can show weaknesses in the sealing with the process tube outer surface.

Prior art patent document published US 2003/0015142 A1 discloses a reaction tube made of quartz and provided with a sleeve-shaped connector sealingly engaging with said tube by means of O-rings located between an outer surface of the tube end and an inner surface of the sleeve-shaped connector receiving said tube end. The sleeve-shaped connector comprises a water pipe for cooling the O-rings. Despite the useful cooling action of the water pipe, the engagement between the O-rings and the tube can show deficiencies, i.e., leaks, essentially due to the manufacturing dimensional and surface tolerances of the tube.

### SUMMARY OF INVENTION

The invention has for objective or technical problem to overcome at least one drawback of the above cited prior art. More specifically, the invention has for objective to provide a safe and tolerance resistant connection to a process tube, i.e., a tube intended to serve as a reaction chamber with gas, notably at high temperatures.

The invention is directed to a connector for a process tube, comprising: an annular body; an engagement bore formed in the annular body, for receiving an end of the process tube; a sealing groove formed in the engagement bore, for receiving at least two annular gaskets for contacting the end of the process tube; wherein the annular body comprises a sealing port fluidly connected with the sealing groove as to allow applying a gas pressure in the sealing groove between the at least two annular gaskets.

According to an exemplary embodiment, the connector further comprises the at least two annular gaskets in the sealing groove, being in various instances two O-rings.

According to an exemplary embodiment, the connector further comprising a ring being rigid and located in the sealing groove between the at least two annular gaskets.

According to an exemplary embodiment, the ring comprises a series of radial holes extending from a radially outer face to a radially inner face of said ring, said radial holes being distributed, in various instances uniformly, along a circumference of said ring.

According to an exemplary embodiment, the annular body further comprises an abutment bore adjacent the engagement bore and for abutting against the end of the process tube when received in the engagement bore, and a process gas port opening out in the abutment bore.

According to an exemplary embodiment, the abutment bore forms an opening providing access to the process tube when received in the engagement bore.

According to an exemplary embodiment, the connector further comprises a closing plate removably mounted on the annular body adjacent the abutment bore, so as to close the opening.

According to an exemplary embodiment, the annular body further comprises a cooling chamber surrounding the sealing groove, a cooling inlet port and a cooling outlet port, fluidly connected to the cooling chamber for circulating a cooling fluid.

According to an exemplary embodiment, the annular body comprises a first annular part forming the engagement bore and the sealing groove, and a second annular part in engagement with the first annular part, the cooling chamber being delimited by the first and second annular parts.

According to an exemplary embodiment, at least one of the first and second annular parts comprises a groove forming the cooling chamber.

According to an exemplary embodiment, at least one of the cooling inlet port and cooling outlet port is formed on one of the first and second annular parts.

The invention is also directed to a process unit comprising: a process tube of alumina with two ends; and a connector sealingly mounted on each of the ends of the process tubes; wherein at least one of the two connectors is according to the invention.

The invention is also directed to a gas process tube machine comprising: a process control unit; and a process unit extending through the process control unit; wherein the process unit is according to the invention.

According to an exemplary embodiment, the gas process tube machine comprises: a process gas flow control unit with at least one process gas inlet and a process gas outlet; a neutral gas flow control unit with at least one neutral gas inlet and a neutral gas outlet connecting to the process gas flow control unit.

Advantageously, the neutral gas outlet is fluidly connected to the sealing port of each of the at least one connector.

According to an exemplary embodiment, the neutral gas flow control unit is configured to apply a neutral gas pressure to the sealing port of the connector of the process unit and to detect a potential decrease of said neutral gas pressure in said connector and issue an alarm in case the decrease is detected.

The invention is also directed to a gas process comprising the following steps: (a) providing a substrate in a process tube; (b) injecting at least one process gas into the process tube; wherein steps (a)-(b) are carried out using a gas process tube machine according to the invention, and at least during step (b), a neutral gas is supplied to at least one of the two connectors, so as to apply a neutral gas pressure to the sealing groove of said at least one connector.

According to an exemplary embodiment, the at least one process gas in step (b) comprises a reactive gas.

Advantageously, the neutral gas is nitrogen and/or argon.

According to an exemplary embodiment, the neutral gas pressure is greater than a pressure of the process gas in the process tube, in various instances by at least 0.1 bar, for example by at least 0.5 bar.

According to an exemplary embodiment, the neutral gas pressure is of at least 0.5 bar and/or maximum of 2 bar.

Advantageously, the gas process further comprises an intermediate step of heating the process tube such that an interior of the process tube reaches a temperature of at least 100° C., in various instances at least 200° C.

According to an exemplary embodiment, the neutral gas pressure is monitored so as to detect a potential decrease of said pressure at least during step (b) and issue an alarm in case the decrease is detected.

The invention is particularly interesting in that it allows to achieve gas tightness within large manufacturing tolerances of the process tube. This also increases the security of the gas process tube machine when in operation when using reactive gas(es) as process gas(es). These large manufacturing tolerances are essentially due to the use of particular material for producing the process tube, like ceramic material, which is difficult to machine. In addition, the operation of the process tube with potentially dangerous gases and also at high temperature increases the hazardous consequences of a process gas leak. It is however understood that the invention remains advantageous at room temperature or at moderate temperatures like above room temperature and up to 100° C. or 200° C., essentially because the security with regard to gas tightness between the connector and the process tube is provided at any temperature.

### BRIEF DESCRIPTION OF THE DRAWINGS

FIG. 1 is a perspective view of a gas process tube machine according to the invention.

FIG. 2 is a detailed view of one end of the process tube of the gas process tube machine of FIG. 1, according to the invention.

FIG. 3 is a longitudinal sectional view of the end of the process tube of FIG. 2.

FIG. 4 is a perspective view of ring located in the sealing groove of the connector, visible in FIGS. 2 and 3.

FIG. 5 is a schematic illustration of the fluid connections of the gas process tube machine according to the invention.

### DETAILED DESCRIPTION

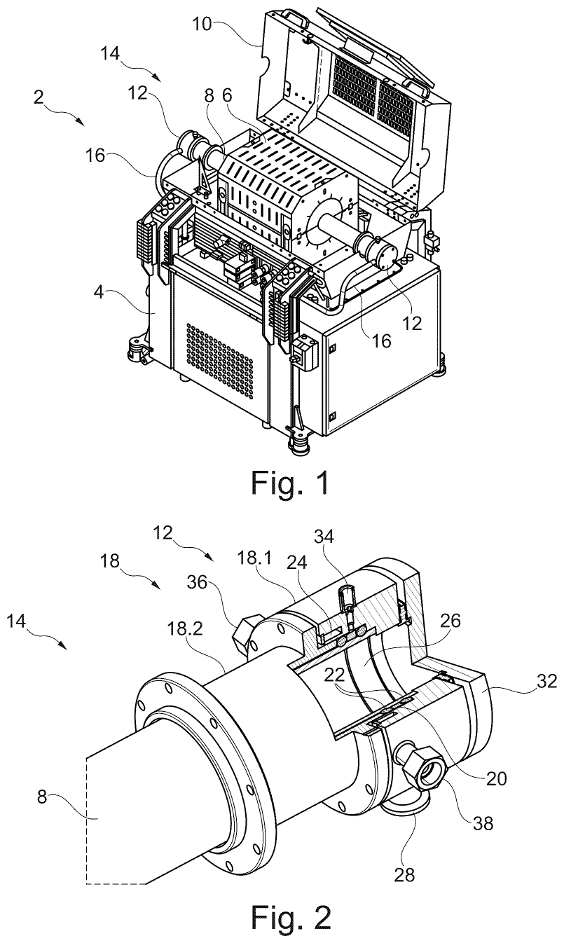

FIG. 1 depicts a gas process tube machine, being for instance a furnace, equipped with a heat process unit, according to the invention.

The gas process tube machine 2 comprises a frame 4 housing various components such as an electric power supply, process gas supplies, a temperature control unit, etc.

The gas process tube machine 2 comprises also a heating unit 6 carried by the frame 4 and supplied and controlled by the mentioned electric power supply and temperature control unit, respectively. The heating unit 6 is comprised of two half-shells housing electrical resistors and insulating material. The two half-shells are movable relative to each other so as to provide access to a cavity of the heating unit 6, for instance to enable placement of the process tube 8. For instance, the upper half-shell can be lifted or removed from the lower half-shell so as to provide access to a tubular cavity intended to receive and house the process tube 8. It shall be mentioned that the process tube 8 can also be inserted into the cavity while the heating unit 6 remains generally closed or by using a totally closed heating cavity, by a longitudinal sliding movement of the process tube 8 into the tubular cavity. As this is apparent, the tubular cavity opens out at each end thereof at the two opposed lateral wall of the heating unit 6. In other words, the process tube 8, when properly functionally positioned in the heating unit 6, extends out of said heating unit at both ends of said process tube 8.

The gas process tube machine 2 further comprises a cover 10 hinged on the frame 4. The cover 10, when closed, i.e., in a lowered position, covers the heating unit 6 and portions of the process tube 8 extending out of the process unit 6, essentially for avoiding contact by an operator with the process tube 8 and/or the heating unit 6 potentially at very high temperatures.

In the gas process tube machine illustrated in FIG. 1, the process tube 8 extends horizontally, so that the gas process tube machine is of the horizontal type. It is to be mentioned that the gas process tube machine can be of the vertical type, i.e., where the process tube extends vertically. The process tube can be also angled.

The process tube 8 is made of refractory material, in order to support high temperatures, e.g., of at least 600° C., in various instances at least 1000° C. The process tube 8 is advantageously made of ceramic alumina. The process tube could be also in quartz or glass. The process tube 8 is hollow so as to receive a substrate intended to undergo a process at high-temperature and/or potentially in the presence of neutral and/or reactive gases.

Still with reference to FIG. 1, we can see that a connector 12 is provided at each end of the process tube 8. The process tube 8 equipped with the two connectors 12 at both ends thereof form a gas process unit 14. The connectors provide gas tight connection between the interior of the tube and gas conduits 16. The connectors 12 shall provide a gas tight connection with the process tube 8 in order to avoid leaks of potentially explosive gases or to prevent ambient air to flow in the tube 8. That gas tight connection is achieved by an appropriate contact of gaskets in the connectors with the outer cylindrical surface of the process tube 8. The latter being made of refractory material is non-metallic and therefore cannot be easily machined. It also shows geometrical dimensions with a certain tolerance being the consequence of its manufacturing process.

FIG. 2 is a perspective view of one end of the gas process unit 14 visible on the gas process tube machine 2 in FIG. 1.

FIG. 2 shows a sectional view of the connector 12. The sectional view is along two longitudinal planes of the process tube 8, meaning that the latter is cut along its longitudinal direction by two planes comprising the longitudinal axis of the process tube.

As this is apparent the connector 12 comprises an annular body 18 forming an engagement bore receiving the end of the process tube 8. A sealing groove 20 is formed in the engagement bore, so as to be directly adjacent to an exterior cylindrical surface of the process tube 8. The sealing groove 20 houses two annular gaskets 22 contacting the exterior cylindrical surface of the process tube 8. The annular body 18 comprises a sealing port 34, fluidly connected with the sealing groove 20 so as to allow applying a gas pressure in the sealing groove 20 between the two annular gaskets 22. The sealing groove 20 with the two annular gaskets 22 forms then a chamber that can be pressurized for ensuring and/or controlling a leak free connection between the annular body 18 and the process tube 8.

Still with reference to FIG. 2, we can observe the presence of a groove forming a cooling chamber 24 for maintaining the two annular gaskets 22 at a limited temperature. A cooling inlet port 36 and a cooling outlet port 38 are formed on the body 18. These two ports are for instance diametrically opposed, being however understood that other angular relative position can be considered.

Further in FIG. 2, we can observe that the annular body 18 comprises an abutment bore 26 directly adjacent the engagement bore, for abutting against the end of the process tube 8 when received in the engagement bore. The annular body 18 can further comprise a process gas port 28 directly fluidly connected with a passage (not visible in FIG. 2) formed in the annular body 18 that opens out in the abutment bore 26.

The abutment bore 26 forms an opening providing a direct access to the interior of the process tube 8. A closing plate 32 is removably mounted on the annular body adjacent the abutment bore 26, so as to close the opening and thereby close the interior of the process tube 8. The closing plate is mounted by means of a series of screw along its periphery, extending through the closing plate and engaging with holes, for instance threaded holes, formed in the annular body 18, being however understood that other fixation means can be considered.

The connector 12 provides therefore a process gas connection to the process tube 8 that is gas tight by virtue of the sealing groove that can be pressurized so as to axially urge the annular gaskets against side walls of the sealing groove and also so as to form a barrier against possible leaks of the process gas towards the ambient air. To that end, the sealing groove is advantageously pressurized with a neutral gas such as nitrogen and/or argon, so that in case of a possible gas leak between the process tube 8 and the connector 12, the pressurized gas in the sealing groove, provided that it is a pressure higher the pressure in the process tube 8, will flow into the process tube 8 instead of having the potentially dangerous process gas flowing out of the process tube 8 to the ambient air.

The gaskets are for instance O-rings but it is understood that other types of gaskets can be considered, like annular gaskets with different sections, like square-like sections, oval sections, sections with a one or several sealing lips, etc.

During operation, i.e., during a gas reactive process and/or heat reactive process with the gas process unit 14, the neutral gas pressure is advantageously kept higher than the pressure of the process gas inside the process tube, so as to maintain the effect of urging the gaskets axially against the side walls of the sealing groove. The pressure difference can be of at least 0.1 bar or even 0.5 bar. The neutral gas pressure does not need to be constant; it can vary over time during the process. Also, the neutral gas pressure can be monitored before and/or during the process so as to detect any leak and issue an alarm when detecting an abnormal pressure decrease.

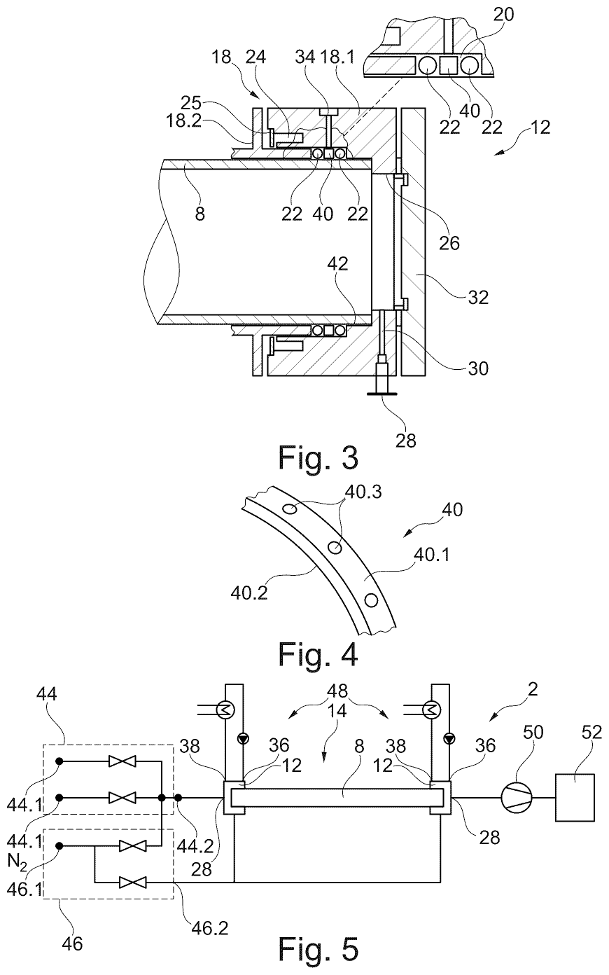

FIGS. 3 and 4 are more detailed views of the connector 12.

FIG. 3 is a longitudinal section view of FIG. 2. We can observe that the annular body 18 is made of first annular part 18.1 forming the sealing groove 20, the engagement bore 42 and the abutment bore 26, and a second annular part 18.2 in engagement with the first annular part 18.1, the cooling chamber 24 being delimited by the first and second annular parts 18.1 and 18.2. For instance, the cooling chamber 24 is formed by a circular groove with a cylindrical shape extending axially and opening out at a front face of the first annular part 18.1 of the body 18, that opening being closed by a ring-shaped plate 25 held against the first annular part 18.1 of the body 18 by the second annular part 18.2 thereof. The latter engages with the first annular part by means of axial screws (not visible).

As this is apparent, the sealing port 34 is in fluidic connection with the sealing groove 20 by a passage formed in the annular body 18, for instance in the first annular part 18.1. A ring 40 is located in the sealing groove 20, between the two annular gaskets 22. That ring 40 forms a spacer holding the two annular gaskets approximately in their end position. The sealing groove 20 comprises two lateral annular side walls against which the annular gaskets 22 are urged or rest when a fluid pressure is applied via the sealing port. For instance, one of these two opposed side walls is formed by a shoulder portion on the first annular part 18.1 whereas the other one is formed by the second annular part 18.2. It is understood that other constructions can be considered while still achieving the above architecture and functions.

Still with reference to FIG. 3, we can see that the cooling chamber 24 is delimited between the first and second annular parts 18.1 and 18.2, these two annular parts being mutually engaged in a liquid tight fashion.

The cooling chamber 24 at least partially surrounds the sealing groove 20, so as to best cool and protect the annular gaskets 22. The cooling chamber 24 can however be axially further or less axially shifted relative to the sealing groove 20 while still providing a satisfactory cooling effect.

FIG. 4 is perspective view of a portion of the ring 40 located in the sealing groove 20 between the annular gaskets 22 in FIGS. 5 and 6. The ring 40 is made of rigid material like plastic, metal or a combination thereof. The ring can show a rectangular cross-section. It shows an outer circular face 40.1 and an inner circular face 40.2. The ring 40 can be provided with a series of holes 40.3 forming passages between the outer circular face 40.1 and the inner circular face 40.2.

FIG. 5 is a schematic illustration of the fluid connections of the process tube machine according to the invention.

The process tube machine 2 can comprise a process gas flow control unit 44 with at least one process gas inlet 44.1 and a process gas outlet 44.2 connected to the process gas port 28 of one of the connectors 12. Such a process gas flow control unit 44 can comprise valve, pressure and flowmeter means for providing an appropriate flow of process gas at a desired pressure. The process gas can be reactive gas like oxygen.

The process tube machine 2 can also comprise a neutral gas flow control unit 46 with at least one neutral gas inlet 46.1 and a neutral gas outlet 46.2 fluidly connected to the sealing port 34 of at least one of the two connectors 12. The neutral gas flow control unit 46 can also be fluidly connected to the process gas flow control unit 44 so as to feed said process gas flow control unit 44 with neutral gas. The neutral gas flow control unit 46 can comprise valve, pressure and flowmeter means for providing an appropriate pressure of the neutral gas, e.g., nitrogen, to the connector(s) 12. The appropriate pressure can be comprised between 1 and 2 bar. The neutral gas flow control unit 46 can be configured so as to to apply a neutral gas pressure to the sealing port of the connector of the process unit and also to detect a potential decrease of said neutral gas pressure in said connector and issue an alarm in case the decrease is detected.

The process tube furnace 2 can also comprise a cooling circuit 48 that is fluidly connected to the cooling inlet port 36 and cooling outlet port 38 of at least one of the connectors 12. The cooling circuit can comprise a liquid as cooling fluid, whereas a gas can also be considered. The cooling circuit 48 is schematically represented as comprising a circulating pump and a heat exchanger, for the sake of clarity. It is however understood the cooling circuit(s) 48 can be different, i.e., more complex or working with another principle. As a matter of example, the cooling circuits 48 can be open circuits fed with a source of fluid and releasing the heated fluid exiting the connectors to the ambient air or to a discharge conduit like a water drain conduit of a building.

The process gas port 28 of the other connector 12 than the one fed with the process gas can be fluidly connected to a vacuum pump and can flow out to a collection unit 52 where the waster process gas or gases are treated and/or released to the ambient air.

1.-21. (canceled)

22. A connector for a process tube, comprising:
an annular body;
an engagement bore formed in the annular body, for receiving an end of the process tube; and
a sealing groove formed in the engagement bore, for receiving at least two annular gaskets for contacting the end of the process tube;
wherein the annular body comprises a sealing port fluidly connected with the sealing groove so as to allow applying a gas pressure in the sealing groove between the at least two annular gaskets.

23. The connector of claim 22, further comprising:
the at least two annular gaskets in the sealing groove; and
a ring being rigid and located in the sealing groove between the at least two annular gaskets.

24. The connector of claim 23, wherein the ring comprises a series of radial holes extending from a radially outer face to a radially inner face of the ring, the radial holes being distributed along a circumference of the ring.

25. The connector of claim 22, wherein the annular body further comprises an abutment bore adjacent the engagement bore and for abutting against the end of the process tube when received in the engagement bore, and a process gas port opening out in the abutment bore.

26. The connector of claim 25, wherein the abutment bore forms an opening providing access to the process tube when received in the engagement bore.

27. The connector of claim 26, further comprising a closing plate removably mounted on the annular body adjacent the abutment bore, so as to close the opening.

28. The connector of claim 22, wherein the annular body further comprises a cooling chamber surrounding the sealing groove, a cooling inlet port and a cooling outlet port, fluidly connected to the cooling chamber for circulating a cooling fluid.

29. The connector of claim 28, wherein the annular body comprises a first annular part forming the engagement bore and the sealing groove, and a second annular part in engagement with the first annular part, the cooling chamber being delimited by the first and second annular parts.

30. The connector of claim 29, wherein at least one of the first and second annular parts comprises a groove forming the cooling chamber.

31. The connector of claim 29, wherein at least one of the cooling inlet port and cooling outlet port is formed on one of the first and second annular parts.

32. A gas process tube machine comprising:
a process control unit; and
a process unit extending through the process control unit and comprising:
a process tube of alumina with two ends; and
a connector sealingly mounted on each of the ends of the process tube;
wherein at least one of the two connectors comprises:
an annular body;
an engagement bore formed in the annular body, for receiving an end of the process tube; and
a sealing groove formed in the engagement bore, for receiving at least two annular gaskets for contacting the end of the process tube;
wherein the annular body comprises a sealing port fluidly connected with the sealing groove so as to allow applying a gas pressure in the sealing groove between the at least two annular gaskets.

33. The gas process tube machine according to claim 32, wherein the process control unit is a heating unit.

34. The gas process tube machine according to claim 32, further comprising:
a process gas flow control unit with at least one process gas inlet and a process gas outlet; and
a neutral gas flow control unit with at least one neutral gas inlet, a neutral gas outlet and connecting to the process gas flow control unit.

35. The gas process tube machine according to claim 34, wherein the neutral gas flow control unit is configured to apply a neutral gas pressure to the sealing port of the connector of the process unit and to detect a potential decrease of the neutral gas pressure in the connector and issue an alarm in case the decrease is detected.

36. A gas process comprising the following steps:
(a) providing a substrate in a process tube; and
(b) injecting at least one process gas into the process tube;
wherein steps (a)-(b) are carried out using a gas process tube machine comprising:
a process control unit; and
a process unit extending through the process control unit and comprising:
a process tube of alumina with two ends; and
a connector sealingly mounted on each of the ends of the process tube;
wherein at least one of the two connectors comprises:
an annular body;
an engagement bore formed in the annular body, for receiving an end of the process tube; and
a sealing groove formed in the engagement bore, for receiving at least two annular gaskets for contacting the end of the process tube;
wherein the annular body comprises a sealing port fluidly connected with the sealing groove so as to allow applying a gas pressure in the sealing groove between the at least two annular gaskets;
and at least during step (b), a neutral gas is supplied to at least one of the two connectors, so as to apply a neutral gas pressure to the sealing groove of the at least one connector.

37. The gas process according to claim 36, wherein the at least one process gas in step (b) comprises a reactive gas.

38. The gas process according to claim 36, wherein the neutral gas pressure is greater than a pressure of the process gas in the process tube, by at least 0.1 bar.

39. The gas process according to claim 36, wherein the neutral gas pressure is of at least 0.5 bar and of maximum 2 bar.

40. The gas process according to claim 36, wherein the neutral gas pressure is monitored so as to detect a potential decrease of the neutral gas pressure and issue an alarm in case the decrease is detected.
